(19) United States
(12) Patent Application Publication
(10) Pub. No.: US 2019/0141860 A1
(43) Pub. Date: May 9, 2019

(54) SMART COOLING SYSTEM FOR AN ELECTRONIC EQUIPMENT ROOM

(71) Applicant: Ching-Chao TSENG, Changhua County (TW)

(72) Inventor: Ching-Chao TSENG, Changhua County (TW)

(21) Appl. No.: 16/239,240

(22) Filed: Jan. 3, 2019

Related U.S. Application Data
(63) Continuation-in-part of application No. 15/188,482, filed on Jun. 21, 2016.

(30) Foreign Application Priority Data
Jul. 3, 2015 (TW) 104121584

(51) Int. Cl. H05K 7/20; G06F 1/20

(52) U.S. Cl. CPC H05K 7/20745; H05K 5/02; G06F 1/20

(57) ABSTRACT

A smart cooling system is mainly applied to an electronic equipment room, in which an extended encircled space is constituted by combining a front extension frame and a rear extension frame with a cabinet, respectively, followed by fitting a cooling apparatus to a plurality of cabinets, to which a pipeline having a path in one single flowing direction is connected in turn. An appropriate amount of air conditioning is guided to a position where it is needed directly and definitely by means of the determination, via temperature sensing units provided within the cabinets, of the demand for air conditioning and the position where the demand comes from. Thereby, not only the cost of construction of air conditioning is reduced significantly, but also the effects of energy conservation and precise cooling are achieved.

### BACKGROUND OF THE INVENTION

### 1. Technical Field

The present invention relates to an air conditioning management system applied to cabinets of an electronic equipment room (or called the data center, server room), particularly to a smart cooling system for directing air into the cabinet directly.

### 2. Description of Related Art

Accordingly, for the current air conditioning management of an electronic equipment room, the whole space of the electronic equipment room is integrally planned. In this way, not only cost is high, but also a lot of space is required to arrange cabinets and considerable space is reserved for setting cold/hot aisles between cabinets, resulting in consuming space. Furthermore, it may waste a lot of energy because air conditioning cycle is mostly performed in the whole space of the electronic equipment room.

As shown in FIG. 1, which is a conventional plan of air conditioning of an electronic equipment room 9, there are four rows of cabinets 90, the rows of cabinets 90 being corresponded to each other in face-to-back configuration, with a certain spacing therebetween, so as to plan the face-to-face spacing as a cold channel 92 while the back-to-back spacing as a hot channel 93. Cold air is guided into the cold channel 92 by using cooling apparatus 91 on two sides, so as to enable cold air flowing into the cabinets 90 from face of the cabinets 90 (as indicated by white arrows in this figure, showing the direction of the flow of cold air) for heat exchange with the electronic equipment in the cabinets 90. Finally, hot air discharged from back of the cabinets 90 is centralized in the hot channels 93 to be recycled by the cooling apparatus 91 (as indicated by black arrows in this figure, showing the direction of the flow of hot air) as cold air again to complete a full air conditioning cycle. In such a plan of the electronic equipment room 9, although the cold channels 92 are independently separated by elevated floor 95 and baffles 94 to prevent cold air from flowing out and thus wasting energy, a lot of space is needed to arrange the cabinets 90. Moreover, the elevated floor 95 also costs a lot.

Further, as shown in FIG. 2, it is another conventional plan of air conditioning of an electronic equipment room 9, in which a cooling apparatus 91 is provided between cabinets 90, such that hot air may be recycled the hot channels 93 from back of the cabinets 90 by the cooling apparatus 91, and cold air is directly supplied to the cold channels 92 (as shown in FIG. 2, white arrows show direction of cold air, black arrows show direction of hot air). A lot of space is still needed to arrange the cabinets 90 in this kind of plan. Although the cost of constructing the elevated floor may be saved, the cold channels 92 and the hot channels 93 are designed to be opened, such that cold air supplied by the cooling apparatus 91 may be consumed in other space in the electronic equipment room 9. Thus, not only energy is wasted, but also the efficiency of management of air conditioning in the cabinet 90 is reduced.

In view of difficulty and drawbacks of planning air conditioning of an electronic equipment room, the inventor researches for improvement and the present invention is finally completed.

### BRIEF SUMMARY OF THE INVENTION

The object of the present invention is to reduce the required space for air conditioning in an electronic equipment room by using air conditioning guiding module, which is applicable to ordinary cabinets and the cost of planning the whole air conditioning may be significantly reduced. In other words, the cost of planning the electronic equipment room is reduced by combining the air conditioning guiding module with the cabinets.

Another object of the present invention is to form an enclosed space by associating the cabinets with the air conditioning guiding module, such that air conditioning is directly guided to the cabinets to achieve the best efficacy of cabinet air conditioning and reduce wasted energy significantly.

To achieve the above objects, the air conditioning guiding module of the present invention is provided to apply to a cabinet, the feature of which is that a front extension frame and a rear extension frame with shaped for fitting the cabinet are provided to respectively connect to a front side and a rear side of the cabinet, the front extension frame having a front space therein, the rear extension frame having a rear space therein, the front space and the rear space being communicated with an accommodating space inside the cabinet when the front extension frame and the rear extension frame are connected to the cabinet, such that the front space, the rear space, and the accommodating space are combined together to form a space isolated from the exterior (i.e., the accommodating space, the front space, and the rear space being combined together to form the enclosed space mentioned in the former paragraph). Further, at least one front guiding module is provided on the front extension frame for guiding external cold air inwards, and a rear guiding module is provided on the rear extension frame for guiding hot air generated inside outwards. Thereby, the air conditioning guiding module is then composed as an air conditioning directing module performing air conditioning process with respect to the interior of the cabinet directly. Effective energy conservation and optimal air conditioning process with respect to the electronic equipment in the cabinet may be achieved by guiding cold air inwards and hot air outwards directly.

Preferably, the front guiding module includes an inlet and a front air distribution unit, as well as the rear guiding module includes an outlet and a rear air distribution unit.

Preferably, the front guiding module may be provided on the top of or on the bottom of the front extension frame, as well as the rear guiding module may be provided on the top of the rear extension frame.

Preferably, a temperature sensing unit is provided within the rear extension frame to regulate the speed of air guided by the front air distribution unit and the rear air distribution unit according to the sensed internal temperature.

Furthermore, the air conditioning guiding module mentioned above may be combined with a cooling apparatus easily and applied to an electronic equipment room with any specification. It is not difficult to plan the space of the electronic equipment room, even though there are multiple cabinets. the present invention may be applied to an ordinary electronic equipment room directly without planning space for air conditioning again. Thus the cost of construction may be reduced. Moreover, air conditioning guiding mechanism for the cabinet saves energy effectively and optimizes performance of heat exchange process for cabinets.

For this reason, the cabinet air conditioning guiding mechanism of the present invention mainly includes at least one cabinet, at least one air conditioning guiding module and a cooling mechanism. In this case, the cabinet is provided therein with an accommodating space for the electronic equipment to be located therein; the air conditioning guiding module, corresponded to the cabinet, includes a front extension frame and a rear extension frame provided to respectively connect to a front side and a rear side of the cabinet, the front extension frame having a front space therein, the rear extension frame having a rear space therein, the front space and the rear space being communicated with the accommodating space inside the cabinet and isolated from the exterior when the front extension frame and the rear extension frame are connected to the cabinet; further, at least one front guiding module is provided on the front extension frame for guiding external cold air inwards, and a rear guiding module is provided on the rear extension frame for guiding hot air generated inside outwards, so as to form an unidirectional flow mechanism directly applied to the interior of the cabinet. The cooling mechanism includes a cold communicating pipeline, a hot communicating pipeline and a cooling apparatus. The cooling apparatus is provided to receive hot air and generate cold air. The cold communicating pipeline respectively connected to the front guiding module and the cooling apparatus is provided to supply cold air generated by the cooling apparatus to the front extension frame. The hot communicating pipeline respectively connected to the rear guiding module and the cooling apparatus is provided to supply hot air discharged from the rear extension frame to the cooling apparatus.

In this way, the cold communicating pipeline and the hot communicating pipeline are used to guide air conditioning for the cabinet directly, so as to effectively prevent cold air generated by the cooling apparatus from escaping toward external environment for saving energy. Moreover, in this direct guidance method, heat exchange may be fully completed in the cabinet and appropriate temperature may be maintained, such that the internal electronic equipment may be performed well.

Preferably, the front guiding module includes an inlet and a front air distribution unit, as well as the rear guiding module includes an outlet and a rear air distribution unit.

Preferably, a temperature sensing unit is provided within the rear extension frame to regulate the speed of air guided by the front air distribution unit and the rear air distribution unit according to the sensed internal temperature.

Preferably, two front guiding modules are provided on the front extension frame to be located on the top of and the bottom of the front extension frame, respectively, and the cooling mechanism includes two cold communicating pipelines, connecting the two front guiding modules to the cooling apparatus from the top and bottom correspondingly and respectively.

Preferably, multiple temperature sensing units are provided in the rear extension frame and respectively located in the positions with different heights, such that the speed of air guided by the corresponding two front guiding modules may be regulated respectively according to the temperature sensed on different heights in the rear extension frame.

Preferably, there are multiple cabinets and multiple air conditioning guiding modules, the numbers of which are corresponded to each other. Moreover, the cold communicating pipeline is provided with multiple connecting ends, connected to the front guiding module of each front extension frame and the cooling apparatus, respectively. The hot communicating pipeline is provided with multiple connecting ends, connected to the rear guiding module of each rear extension frame and the cooling apparatus, respectively.

Additionally, in the cabinet air conditioning guiding mechanism of the present invention, the front space of the front extension frame and the rear space of the rear extension frame may be further used to accommodate related accessories required by electronic equipment, such as a power distribution device, a cabling management device and so on. Thus, the influence on air flow due to the jam-packed cabinet may be avoided so as to keep superior fluidity of air flow and thus enhance efficiency of heat dissipation by means of making good use of this additional space.

Preferably, the power distribution device installed in the front space or the rear space is provided on one side thereof with a plurality of power supply units spaced from each other, each power supply unit being corresponded to a location reserved for accommodating an electronic equipment in the cabinet.

To sum up, in addition to the direct guidance of external air conditioning for the cabinet via the cold and hot communicating pipelines, the air conditioning guiding mechanism of cabinet disclosed in the present invention is also capable of regulating the front guiding module located in a position, corresponding to the position of the temperature sensing unit, to increase (or decrease) the speed of air guided thereby, according to the temperature of the electronic equipment at different positions within the cabinet by the use of the internal temperature sensing units, so as to form the effect of internal guidance of air conditioning, energy conservation, and optimization of air conditioning management.

According to the configuration of the present invention mentioned above, a smart cooling system is formed when being applied to an electronic equipment room practically. In this case, some members are redefined. For example, the cold and hot communicating pipelines are redefined as the first and second pipelines, and the front and rear air distribution units are redefined as the first and second air distribution units. The smart cooling system comprises:

a cooling apparatus provided for cooling a plurality of cabinets and defining a controller to adjust output of air conditioning;

the plurality of cabinets, each having an accommodating space therein for locating electronic equipment, each cabinet further comprising a front extension frame forming a front space communicated to the accommodating space, and a rear extension frame forming a rear space communicated to the accommodating space;

a first pipeline connected to the cooling apparatus and communicated to the front spaces of the cabinets in turn in one single path, for supplying cold air to the front spaces from the cooling apparatus;

a second pipeline connected the cooling apparatus and communicated to the rear spaces of the cabinets, for recycling hot air to the cooling apparatus from the cabinets;

at least one temperature sensing unit provided in the rear space of each cabinet to acquire a cooling demand of each cabinet;

a first air distribution unit provided in the front space of each cabinet to regulate the speed of cold air flowing inwards from the first pipeline according to the cooling demand of each cabinet; and

a second air distribution unit provided in the rear space of each cabinet to regulate the speed of hot air flowing toward the second pipeline according to the cooling demand of each cabinet;

wherein the controller is allowed for regulating output of air conditioning of the cooling apparatus according to the cooling demands of the cabinets.

Preferably, the first pipeline is communicated to an upper side of the front space of each cabinet, the second pipeline is communicated to an upper side of the rear space of each cabinet, and the temperature sensing unit is provided in an upper position of the rear space of each cabinet.

Preferably, the smart cooling system further comprises a third pipeline and a plurality of third air distribution units, the third pipeline being connected to the cooling apparatus and communicated to lower sides of the front spaces of the cabinets in turn in one single path for supplying cold air to the front spaces from the cooling apparatus, each third air distribution unit being provided in the front space of each cabinet to regulate the speed of cold air flowing inwards from the third pipeline according to the cooling demand of each cabinet.

Preferably, the number of the temperature sensing units in the rear space of each cabinet may be two or more, and the temperature sensing units are respectively located at positions from upper to lower side of the rear space for acquiring cooling demands at the upper to lower positions of each cabinet, the first air distribution unit regulating the speed of cold air flowing from the first pipeline according to the cooling demands of the upper positions of each cabinet, and the third air distribution unit regulating the speed of cold air flowing from the third pipeline according to the cooling demands of the lower positions of each cabinet.

Preferably, the first pipeline is provided with a plurality of downward-extending portions connecting to an upper side of the front extension frame of each cabinet, and the third pipeline is also provided with a plurality of upward-extending portions connecting to a lower side of the front extension frame of each cabinet, as well as each downward-extending portion and upward-extending portion is preferably not longer than 30 cm in length.

The elevated temperature sensed by the temperature sensing units in the rear extension frame (rear space) may be caused by heat distributed from the operating electronic equipment in the cabinet, and thus considered as a demand on heat dissipation (cooling demand). Areas in the cabinet required for heat dissipation may be known specifically by using the temperature sensing unit provided in different positions, and the front guide modules in corresponding positions may be adjusted according to requirements, such that cold air may be fully guided to the area in need, to achieve the mechanism of guidance of air conditioning in the interior of each cabinet according to the demand. Furthermore, in the present invention, information sensed by each temperature sensing unit in the cabinet may be integrated into cooling demand of each cabinet, and the built-in controller of the cooling apparatus is provided to supply appropriate amount of cold air by calculating according to the cooling demand of each cabinet, so as to achieve the effect of energy conservation.

Generally, an electronic equipment room is capable of accommodating a plurality of cabinets, and each cabinet is equipped with much electronic equipment. The amount of heat generated by each electronic equipment is distinct due to distinct purpose (such as operation, storage and etc.), operation state (such as in high-speed operation state, in low-speed operation state, resting state and etc.), operation time period and so on. Therefore, the positions and demands for heat dissipation (cooling) are constantly changed in the electronic equipment room. The conventional way of providing a uniform air conditioning in the electronic equipment room is impossible to give consideration to both energy conservation and cooling effect. For example, the cabinet close to the cooling apparatus usually obtains sufficient cooling, while the cabinet far from the cooling apparatus is not cooled enough. In other words, it is necessary to increase the output of air conditioning of the cooling apparatus, resulting in excessive energy consumption, in order to ensure the cooling effects for the cabinets far from the cooling apparatus.

On the contrary, the smart cooling system of the present invention is capable of adjusting the output of air conditioning according to the cooling demands of the cabinets, with the cold communicating pipeline (first pipeline) supplying cold air in one single path and the air distribution unit of each cabinet introducing an appropriate amount of cold air according to its own demand. Thereby, supplying cold air to each cabinet and the position of each cabinet where the demand comes from is ensured together with energy conservation.

For understanding the above-mentioned objects, effects and features of the present invention more specifically, preferred embodiments of the present invention are described in accompany with drawings as follows:

### BRIEF DESCRIPTION OF THE SEVERAL VIEWS OF THE DRAWINGS

FIG. 1 is a diagram of a conventional plan of air conditioning of an electronic equipment room;

FIG. 2 is a diagram of another conventional plan of air conditioning of an electronic equipment room;

FIG. 3 is a diagram of the assembly of the air conditioning guiding module and the cabinet;

FIG. 4 is a diagram of heat exchange in the cabinet;

FIG. 5 is a diagram of appearance of an example of multiple cabinets;

FIG. 6 is a diagram of appearance of another example of multiple cabinets;

FIG. 7 is a diagram of guidance of air conditioning within the cabinet according to one embodiment;

FIG. 8 is a diagram of guidance of air conditioning within the cabinet according to another embodiment;

FIG. 9 is a perspective diagram of a preferred embodiment;

FIG. 10 is a diagram of corresponding position of the power supply unit;

FIG. 11 is a diagram showing the arrangement a power distribution device and a cabling management device;

FIG. 12 is a diagram showing the arrangement of the power distribution device in another angle of view; and

FIGS. 13 to 15 are schematic diagrams showing automatic guidance (distribution) of air conditioning in the states of practical application according to a further embodiment of the present invention.

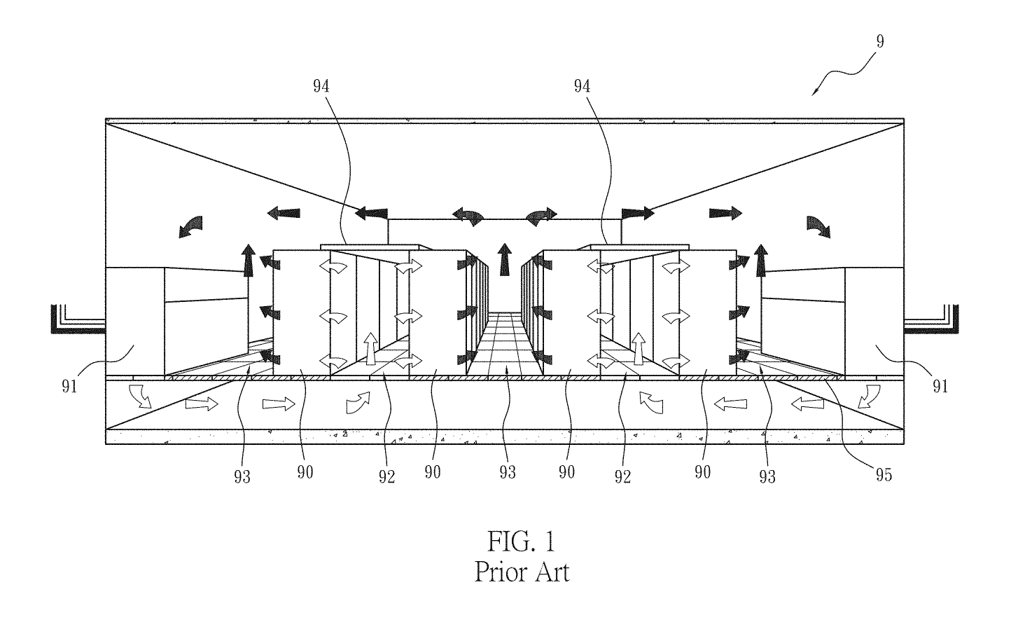

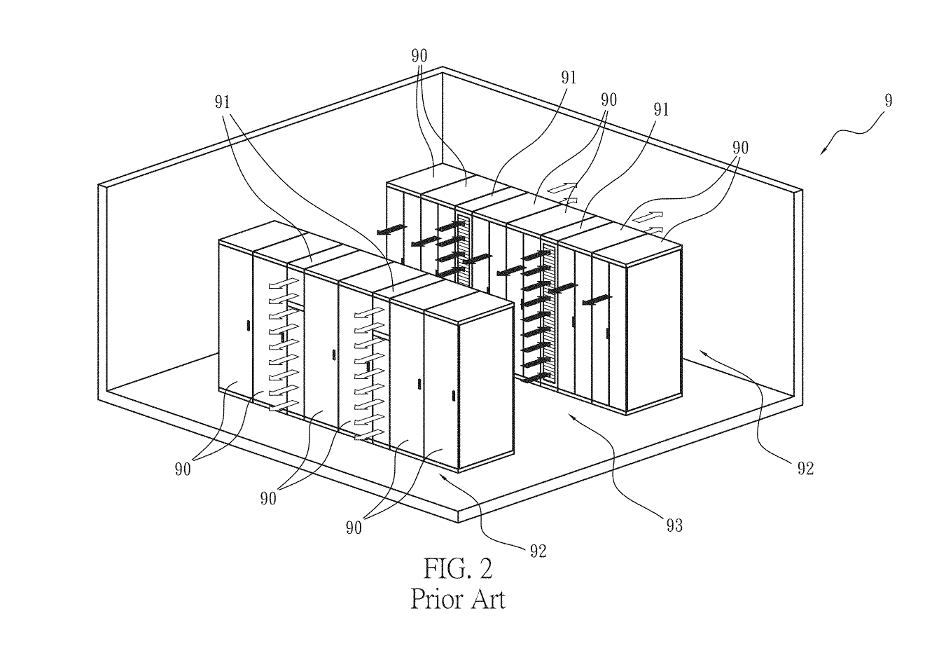

### DETAILED DESCRIPTION OF THE INVENTION

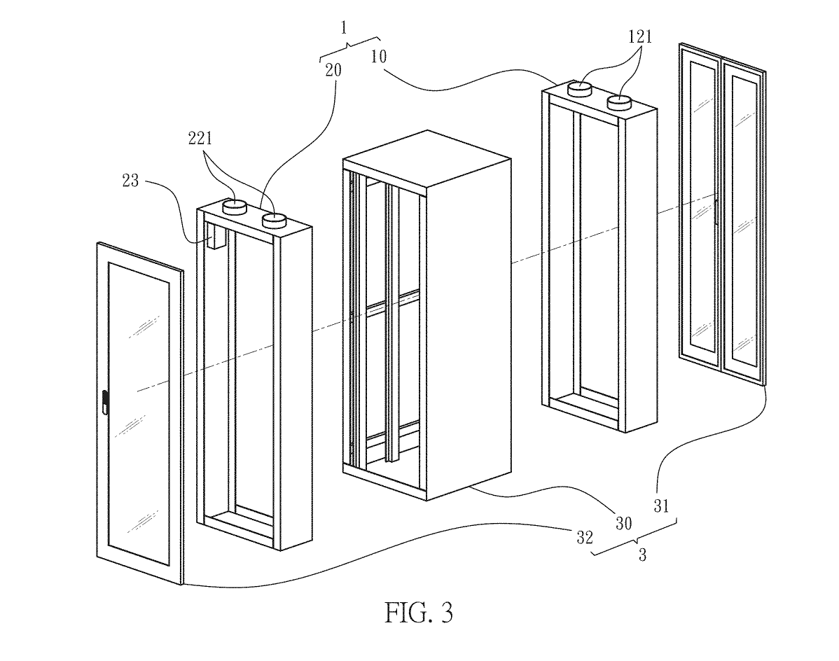

Referring to FIGS. 3 to 5, in the embodiment of the present invention, an air conditioning guiding module 1 on the front and rear sides of the cabinet 3 is provided to form an enclosed air conditioning configuration, so as to guide air conditioning into the cabinet 3 directly for heat exchange, and then save energy wasted outside of the cabinet 3. Moreover, the width required for cold and hot channels in a conventional plan of air conditioning of an electronic equipment room having side by side cabinets is reduced significantly.

In this case, the air conditioning guiding module 1 includes a front extension frame 10 and a rear extension frame 20 shaped for fitting the cabinet 3. The front extension frame 10 is provided therein with a front space 11, one side of which is provided to connect to a front side of a cabinet body 30, and the other side thereof is provided to be enclosed by a front board 31 of the cabinet 3. The rear extension frame 20 is provided therein with a rear space 21, one side of which is provided to connect to a rear side of the cabinet body 30, and the other side thereof is provided to be enclosed by a rear board 32 of the cabinet 3. Thereby, the front space 11 and the rear space 21 are communicated with an accommodating space 301 within the cabinet body 30 when the front extension frame 10 and the rear extension frame 20 are connected to the cabinet 3, so as to form a separate space isolated from the exterior. In practice, the front extension frame 10 is one extension extending from a front side of the cabinet 3 and having the front space 11 communicated to the accommodating space 301 inside the cabinet 3, as well as the rear extension frame 20 is the other extension extending from a rear side of the cabinet 3 and having a rear space 21 communicated to the accommodating space 301 inside the cabinet 3.

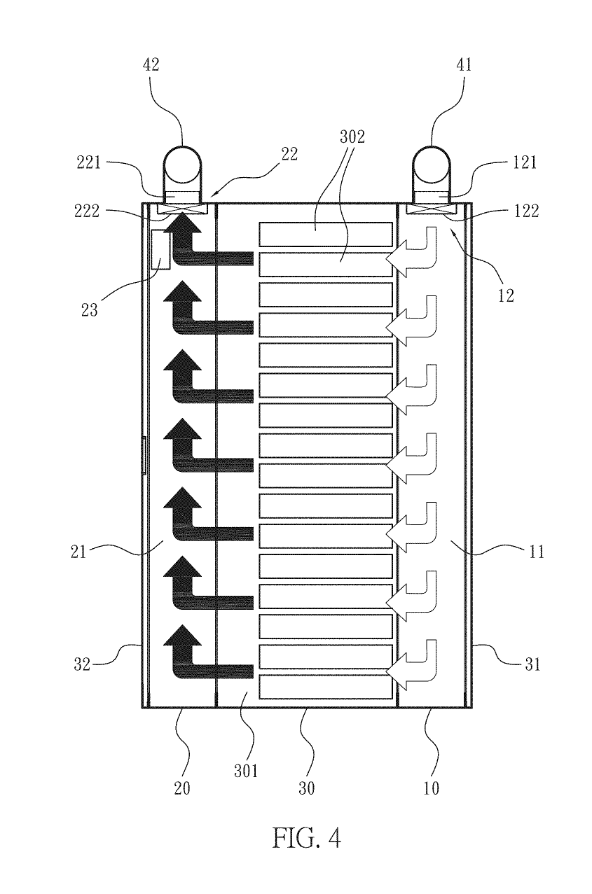

A front guiding module 12 is provided on the front extension frame 10 for guiding external cold air inwards, while a rear guiding module 22 is provided on the rear extension frame 20 for guiding hot air generated inside outwards, such that cold air guided from the front guiding module 12 (as illustrated by white arrows in FIG. 4) is provided for heat exchange with the equipment 302 in the cabinet body 30, and hot air may be then guided out by the rear guiding module 22 after heat exchange (as illustrated by black arrows in FIG. 4), to achieve the object of direct guidance of air conditioning for the cabinet 3.

In one possible embodiment, the front guiding module 12 includes an inlet 121 and a front air distribution unit 122, while the rear guiding module 22 includes an outlet 221 and a rear air distribution unit 222, the inlet 121 and the outlet 221 used for being connected to the cold communicating pipeline 41 and the hot communicating pipeline 42 of the air conditioning system, respectively, while the front air distribution unit 122 and the rear air distribution unit 222 being used for controlling the flowing direction of cold and hot air.

Furthermore, in the embodiment of the present invention, the rear extension frame 20 is further provided therein with a temperature sensing unit 23, possibly located in a position close to the rear guiding module 22. Thereby, the speed of guidance of air of the front guiding module 12 and the rear guiding module 22 is regulated effectively on the basis of elevated temperature of the equipment 302 within the cabinet 3 after heat exchange, so as to achieve optimized control and energy-saving effect of air conditioning.

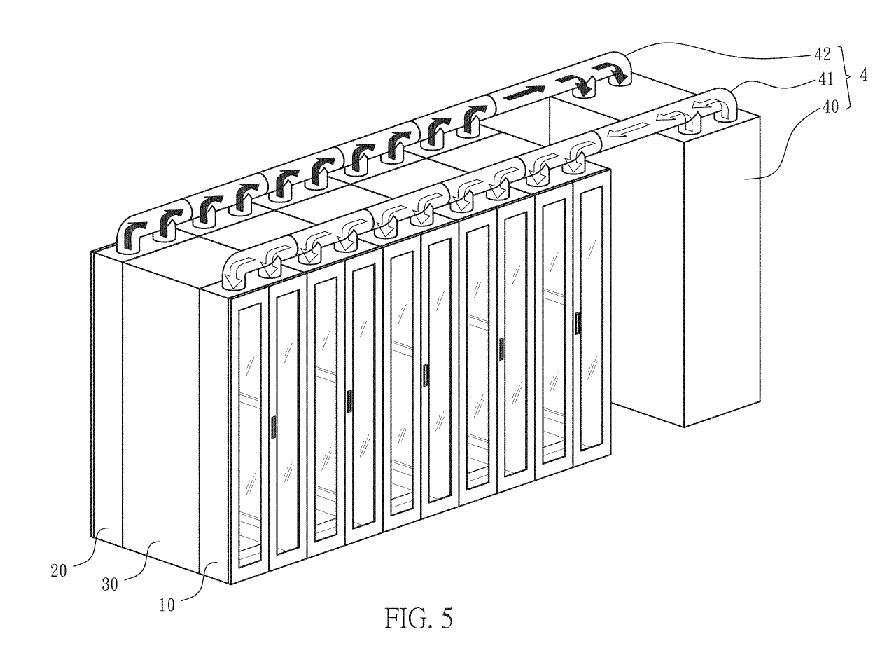

FIG. 5 is a diagram of appearance of an example of multiple cabinets, applicable to an electronic equipment room, in which multiple cabinets 3 associated with the above-mentioned air conditioning guiding module 1 are provided side by side, and a cooling mechanism 4 is provided to guide air conditioning for each cabinet 3 directly. The cooling mechanism 4 includes a cold communicating pipeline 41, a hot communicating pipeline 42, and a cooling apparatus 40. The cooling apparatus 40 is used for receiving hot air and generating cold air. The cold communicating pipeline 41 is provided with a plurality of connecting ends connected to the inlet 121 of each front guiding module 12 and the cooling apparatus 40, respectively, for supplying cold air generated by the cooling apparatus 40 to each front extension frame 10. The hot communicating pipeline 42 is provided with a plurality of connecting ends connected to the outlet 221 of each rear guiding module 22 and the cooling apparatus 40, respectively, for supplying hot air guided from each rear extension frame 20 to the cooling apparatus 40. In this embodiment, the cold communicating pipeline 41, each front guiding module 12, the hot communicating pipeline 42, and each rear guiding module 22 are all located above each air conditioning guiding module 1, such that cold air may be guided into the front space 11 followed by flowing downwards naturally, for facilitating heat exchange with the electronic equipment 302 in the cabinet 3, while hot air in the rear space 21 is allowed to flow upwards naturally after heat exchange, for facilitating the rear guiding module 22 to guide hot air outwards smoothly from the top thereof.

In the practical application of the present invention, neither re-planning or re-building the electronic equipment room, nor replacing the original cabinets 3 is required. The air conditioning guiding system with direct guidance is completed, if only an appropriate air conditioning guiding module 1 is combined with the cabinets 3 followed by connecting the cooling apparatus 40 to the cold communicating pipeline 41 and the hot communicating pipeline 42. Furthermore, it is also possible for a user to arrange the cooling apparatus 40 corresponding to the number of cabinets 3 as required to meet the cooling demand of each cabinet 3 on the basis of the configuration of air conditioning guiding mechanism for cabinets 3 of the present invention.

In one possible embodiment, the pipelines of the cold communicating pipeline 41 and the hot communicating pipeline 42 may be composed of several pipes, according to the requirement of construction (the number of the cabinets 3), so as to connect to the cooling apparatus 40 and each cabinet 3 easily, and thereby complete the plan of cold/hot channels of the air conditioning system without re-building the configuration of the electronic equipment room, so as to reduce the cost of constructing electronic equipment room significantly. In practice, the cold and hot communicating pipeline 41, 42 may be arranged according to the location of the cabinet 3, such that the present invention may be well applied to a restricted area. Taking the cold communicating pipeline 41 as an example, it is primary to communicate the front spaces 11 of these cabinets 3 in turn in one single path (in one single flowing direction), such that providing cold air to each cabinet 3 is ensured. As for the hot communicating pipeline 42, it is used for the purpose of recycling hot air of each cabinet 3 to the cooling apparatus 40, such that there is less requirement for the arrangement of path.

Additionally, each combination of the cabinet 3 and the air conditioning guiding module 1 is provided therein with a temperature sensing unit 23 correspondingly, according to the configuration of the present invention, so as to control the speed of air conditioning properly. Thereby, an appropriate amount of cold air may be guided in and hot air is then guided out when the system is in operation according to the demand of interior of each cabinet 3 (i.e., heat generated by the electronic equipment 302 in each cabinet body 30), such that cold air provided by the cooling apparatus 40 may be guided into the cabinet 3 in need in turn certainly in a path in one single flowing direction to avoid wasting energy.

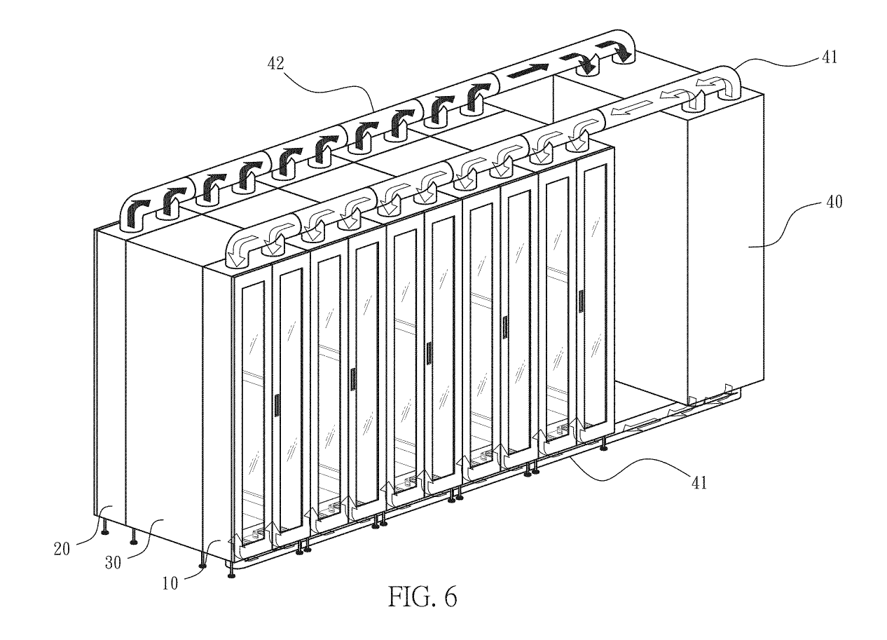

Referring to FIG. 6 together, in another embodiment of the present invention, each front extension frame 10 of air conditioning guiding module 1 may be further respectively provided on the top and the bottom thereof with the front guiding module 12 connected to the cooling apparatus 40 from the top and the bottom via two cold communicating pipelines 41, respectively. The lower cold communicating pipelines 41, as shown in this figure, are arranged by means of a predefined space reserved under the cabinet body 30, the front and rear extension frames 10 and 20 held up by the use of legs. Naturally, if the elevated floor is provided in the original electronic equipment room, it is also possible for the outlet of the elevated floor to be corresponded to the front guiding module 12 on the bottom of the front extension frame 10 directly, instead of the cold communicating pipeline 41 in this embodiment, so as to reduce the cost of construction. Thereby, cold air may be guided into the front extension frame 10 from both the top and bottom, such that each electronic equipment 302 in the cabinet 3 may be contacted with cold air, regardless of the height of position thereof, for heat exchange.

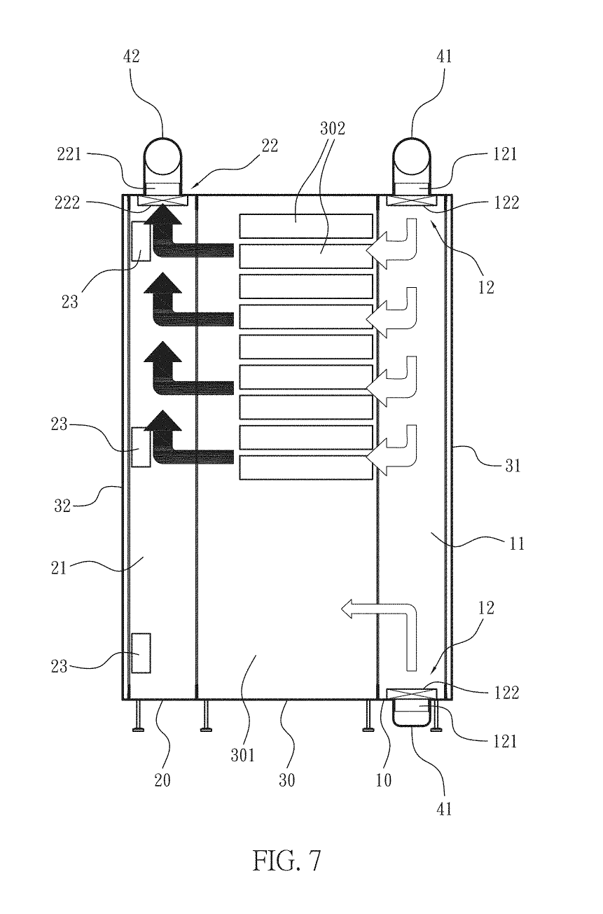

Referring to FIG. 7 together, each rear extension frame 20 is further provided with a plurality of temperature sensing units 23, installed at different heights, respectively. Taking three positions, i.e., upper, middle and lower heights as examples in this disclosure, the speed of air guided by the front guiding module 12 may be further regulated on the basis of the temperature varied with respect to height of the position, correspondingly. As shown in this figure, elevated temperature is sensed by the upper temperature sensing unit 23, if equipment 302 is located in the upper position in the cabinet body 30 mostly (as illustrated by wider black arrows in this figure, the generated hot air being sensed by the temperature sensing unit 23 in the corresponding position). At this time, the front guiding module 12 on the top of the front extension frame 10 may be regulated to speed up the guidance of cold air (as illustrated by wider white arrows in this figure). Cold air may be supplied appropriately according to the requirement for heat dissipation of the electronic equipment 302 in the cabinet body 30, so as to enhance the efficiency of heat exchange with the electronic equipment 302, and further achieve the effect of internal guidance of air conditioning. For the same reason, the front guiding module 12 on the bottom of the front extension frame 10 may be regulated to speed up the guidance of cold air, if higher temperature is sensed by the lower temperature sensing unit 23. Moreover, the front guiding modules 12 on the top and bottom of the front extension frame 10 may be regulated to speed up the guidance of cold air together, if elevated temperature is sensed by all of the temperature sensing units 23.

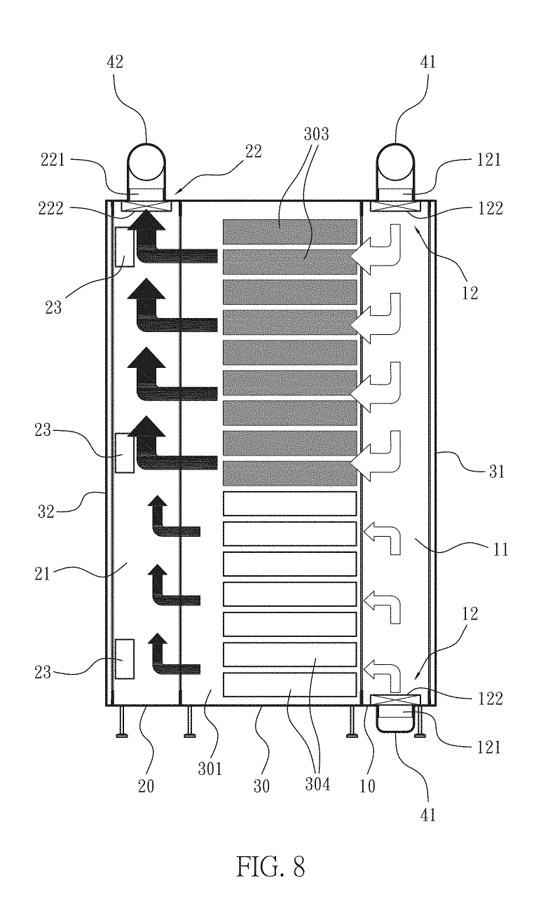

Another aspect of embodiment is shown in FIG. 8. In this example, much electronic equipment 303, 304 is mounted in the cabinet body 30 from top to bottom, and may be divided, however, into electronic equipment 303 in high-speed operation state and electronic equipment 304 in standby or resting state according to the state of use or operation of the electronic equipment.

It is well known that each electronic equipment in the cabinet may be not always situated in a high-speed operation state, or in a standby or resting sate. The specific state is varied according to the requirement of application. Moreover, a large amount of heat is generated when the electronic equipment 303 is situated in the high-speed operation state, and a smaller amount of heat is then generated when the electronic equipment 304 is situated in the standby or resting state. For a general air conditioning configuration of equipment room, in which each electronic equipment is treated equally, excessive cooling of air conditioning is provided as an inevitable waste of energy if the high-speed operation state is taken as the basis for consideration. Nevertheless, performance and service life of electronic equipment are influenced due to insufficient cooling of air conditioning if the standby or resting state is taken as the basis for consideration.

Thus, in the aspect as illustrated in FIG. 8, it is possible for the present invention to solve the problems of supply-demand imbalance and high energy consumption. A large amount of heat is generated by the electronic equipment 303 provided in the upper position in the cabinet body 30 when this electronic equipment is situated in the high-speed operation state (as illustrated by wider black arrows in the upper middle of this figure). Moreover, a small amount of heat is generated by the electronic equipment 304 provided in the lower position in the cabinet body 30 when this electronic equipment is situated in the standby or resting state (as illustrated by thinner black arrows in the lower middle of this figure). At this time, different amount of heat is generated. Thereby, when the significantly elevated temperature is sensed by the upper temperature sensing unit 23, the front guiding module 12 in the corresponding position (top position) may be driven to speed up the guidance of cold air (as illustrated by wider white arrows in the upper middle of this figure), so as to enhance the efficiency of cold air supply for the elevated temperature area in the cabinet 3 directly, while the original speed of supply for other constant temperature areas is kept unchanged (as illustrated by thinner arrows in the lower middle of this figure). Thereby, the effects of direct guidance of air conditioning to the interior and energy conservation are achieved.

Naturally, in addition to the aspect disclosed above, partial or whole demand on heat dissipation of each cabinet 3 may be determined in the present invention according to specific variation of temperature at different heights in the cabinet 3, so as to further guide air conditioning partially in each cabinet 3 directly, or to convert frequency and adjust output power of the cooling apparatus 40 automatically according to the total demand of all of the cabinets 3 as well as to avoid high energy consumption resulted from supplying cold air excessively. Thereby, the effects of energy conservation and reasonable control of air conditioning are achieved. In a possible embodiment, the cooling apparatus 40 and the cabinets 3 are planned according to maximum power. For example, the maximum power of air conditioning provided by the cooling apparatus 40 is 50 k, while the power of air conditioning consumed by each cabinet in high-speed operation state is 10 k, and thus the cooling apparatus 40 may be served for five cabinets 3 correspondingly (as shown in FIG. 5 or FIG. 6) for responding the cooling demands of the cabinets 3 certainly. However, each electronic equipment in the cabinet 3 is not always situated in the high-speed operation state, such that the demand on heat dissipation of each cabinet 3 may be lower than 2 k if each electronic equipment is situated in the standby or resting state, or may be 2-8 k if part of the electronic equipment is situated in the standby state while another part of the electronic equipment is situated in the operation state, or may be 8-10 k if each electronic equipment is situated in the operation state. Therefore, the total demand on heat dissipation of the five cabinets 3 is very likely to be lower than 40 k or lower than 30 k, even lower than 20 k according to different time periods. Thus, a large amount of waste of energy will be resulted, in case of continuous output of the cooling apparatus 40 at the maximum power of 50 k. For the air conditioning guiding mechanism of the cabinet according to the present invention, the built-in controller of the cooling apparatus 40 is allowed to receive the demand on heat dissipation from each cabinet 3 (temperature sensing unit 23) as well as to convert frequency and adjust output power of the cooling apparatus 40 automatically according to the total demand of all of the cabinets 3, so as to achieve the best effect of energy conservation and the control of air conditioning in each cabinet in the electronic equipment room.

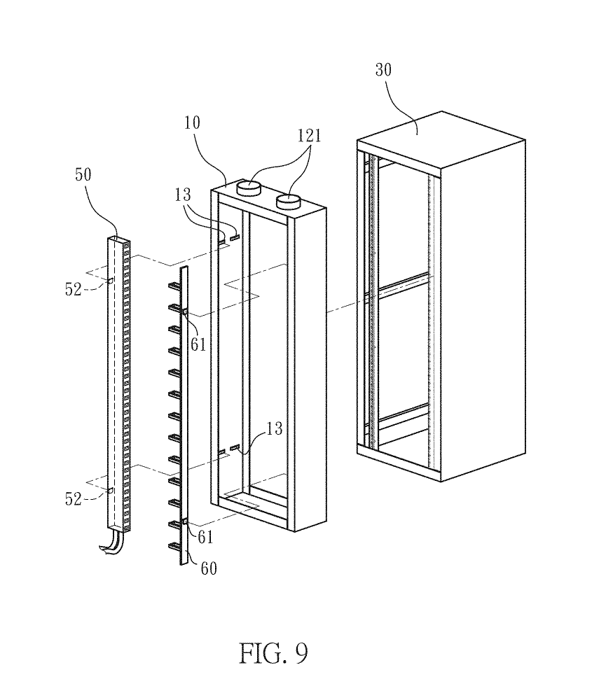

Additionally, in the configuration disclosed by the present invention, the front space 11 or the rear space 21 are further used to place the required related components of the equipment in the cabinet. As shown in FIG. 9, a plurality of engaged portions 13 are provided on two sides of the front extension frame 10, to be engaged with predefined objects, such as the power distribution device 50 or the cabling management device 60 in most cases, if necessary. Moreover, the power distribution device 50 and the cabling management equipment 60 are provided on the back side thereof with corresponding engaged portions 52, 61, respectively, to be engaged with the engaged portions 13 easily and then installed on the sides of the front space 11.

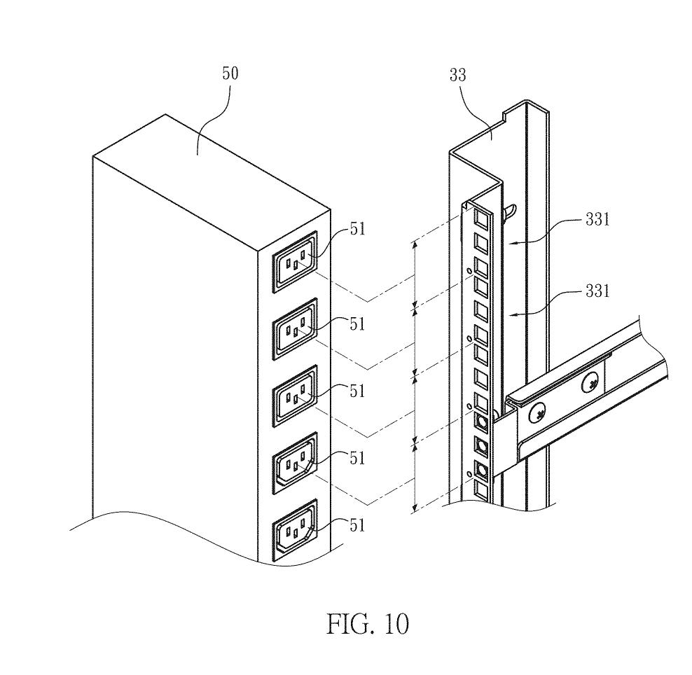

Referring to FIG. 10 together, a general cabinet body 30 is provided therein with brackets 33 for fastening electronic equipment. Each bracket 33 is provided therein with a plurality of fastening spacings 331 (the height of each fastening spacing 331 being U according to the standard of EIA-310-D specified by Electronic Industries Association, 1 U=1.75 inches=44.45 mm), for installing specified electronic equipment. Moreover, the power supply unit 51 is provided on one side thereof with a plurality of power distribution devices 50, such that each power supply unit 51 may be in parallel with each corresponding fastening spacing 331 (i.e., the height spacing of the power supply units 51 conforming to U specification). Thereby, each electronic equipment installed in the cabinet 3 may be applicable to one power supply unit 51 without the problem of insufficient length of wiring or messy wiring.

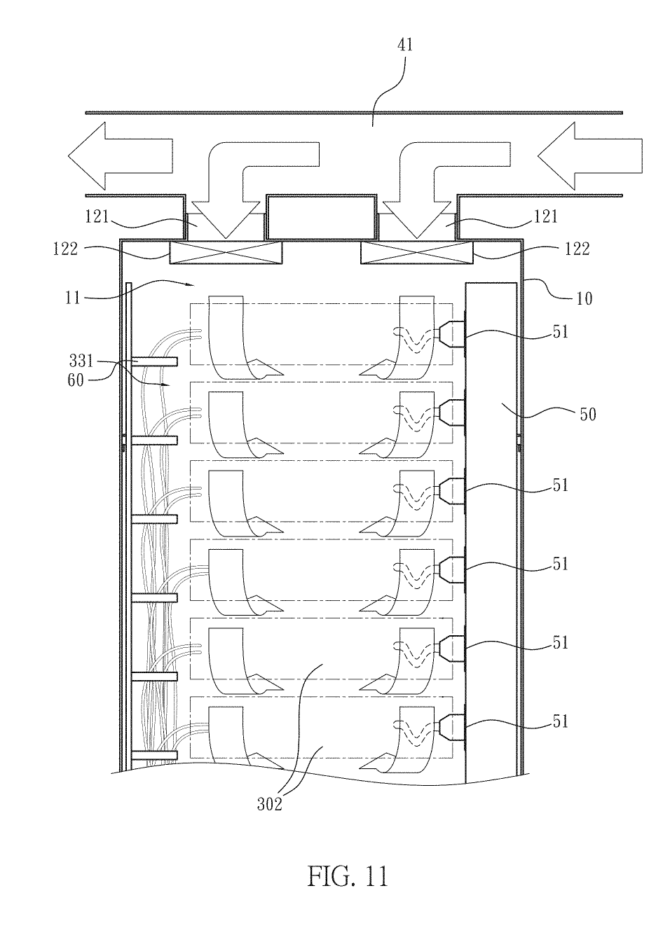

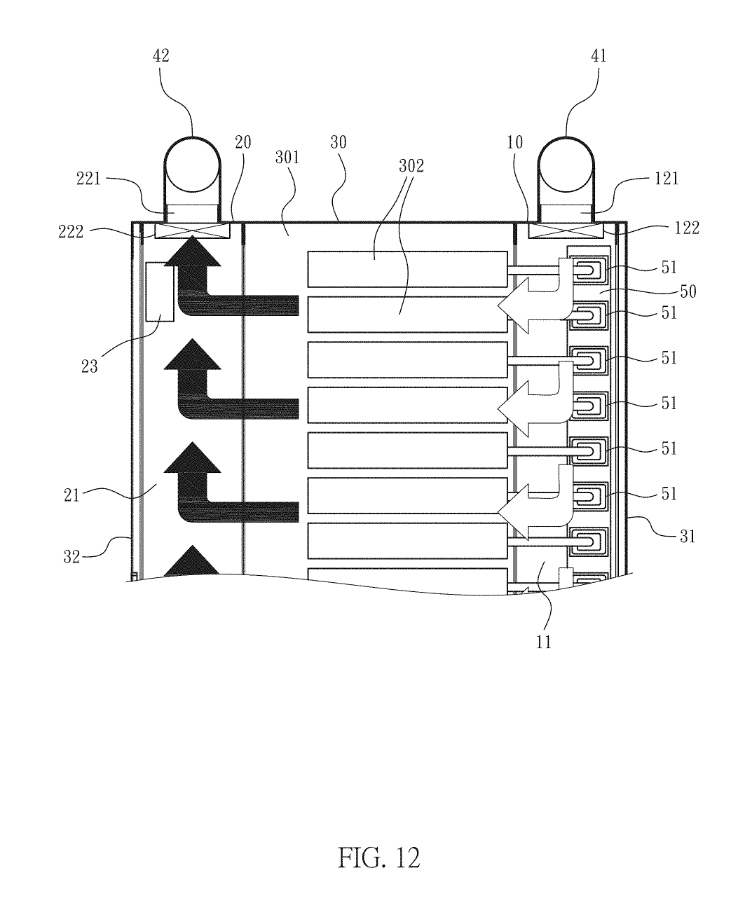

Referring to FIGS. 11 and 12 together, the problem of limited and jam-packed space within the cabinet body 30 may be solved by means of the proper use of the front space 11, such as installing the power distribution device 50 in the front space 11. Moreover, the power distribution device 50 conforming to U standard (per U design) is used to enable more excellent arrangement of wiring, or the cabling management equipment 60 is mounted in the front space 11 so as to manage the wiring by means of the front space 11 to smoothen the guidance of air in the cabinet 3 and improve the performance heat dissipation in the cabinet 3.

A lot of drawbacks of the conventional electronic equipment room, such as, (1) the problem of wasting much energy in an opening air conditioning environment; (2) the problem of partial overheat in the cabinet which is hard to be solved by integrally supplying cold air, because energy is wasted in areas without cooling demand if the performance of supplying cold air is enhanced; (3) high cost of constructing the electronic equipment room and cabinets, too large space required and etc., may be solved by means of the air conditioning guiding mechanism of the present invention. In the present invention, the control of demand on heat dissipation for each cabinet, and direct guidance of air conditioning for partial area in the cabinet may be achieved, so as to construct an optimized air conditioning mechanism and energy conservation management.

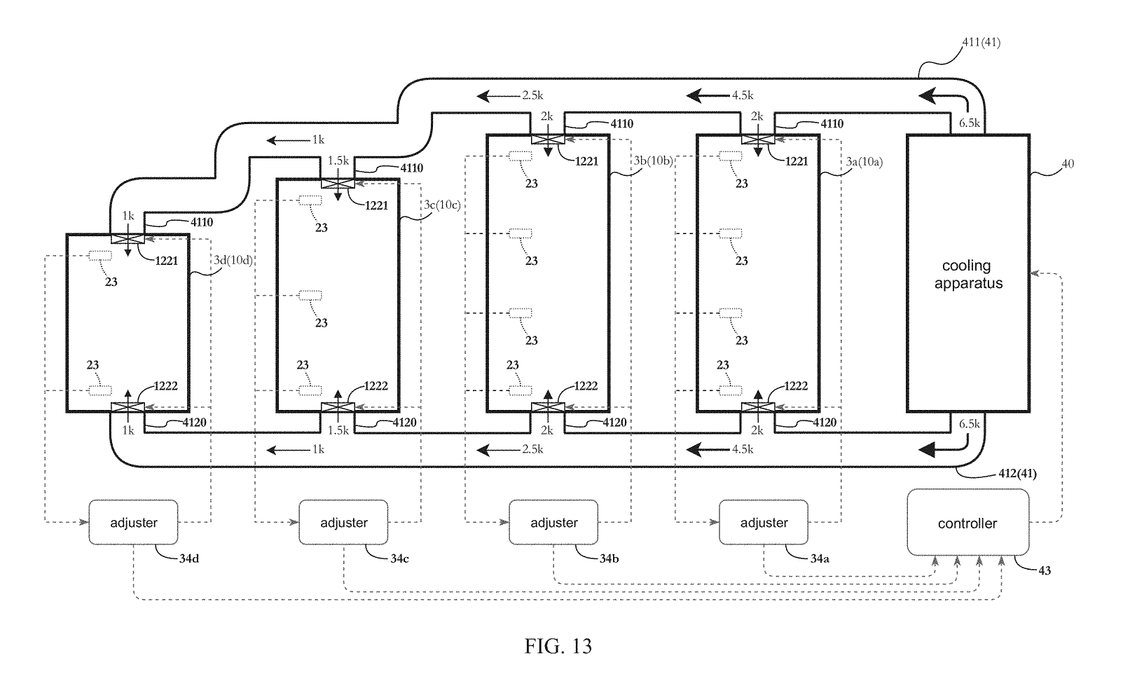

On the basis of the configuration of the present invention, a smart cooling system having low cost of construction together with energy conservation and high performance is formed in accordance with the way of installation of equipment and distribution of air conditioning when it is applied to an electronic equipment room practically. The concept of extending rooms in front and in back of each cabinet 3 is primarily used to install equipment. The cabinet 3, as shown in FIG. 13, may be provided in different sizes, respectively (such as, 2 m high cabinet 3a, 3b, 1.8 m high cabinet 3c, and 1.6 m high cabinet 3d). According to the concept of the present invention, it is only necessary to carry on-specification front extension frames 10a, 10b, 10c, 10d and rear extension frames 20 (not shown in this figure), followed by connecting the cooling apparatus 40 to the cabinets 3a, 3b, 3c, 3d via the cold communicating pipeline 41 and the hot communicating pipeline 42 (not shown in this figure), so as to complete installation easily. Thereby, neither the change of the cabinets 3 nor the reconstruction of the space of equipment room may be required, such that a large amount of unnecessary expense is reduced.

The cold communicating pipeline 41 is started from the cooling apparatus 40 and then connected to each cabinet 3 one by one in a path in one single flowing direction. In this case, the upper cold communicating pipeline 41 is defined as a first pipeline 411, the lower cold communicating pipeline 41 is defined as a third pipeline 412, and the hot communicating pipeline 42 connected to the rear extension frame 20 (located at the top side, as referring to FIGS. 7 and 8 cooperatively) is defined as a second pipeline. The first pipeline 411 is connected above the cooling apparatus 40, and is provided, along the path in the single flowing direction, with a plurality of downward-extending portions 4110 communicated to the top of the front spaces of cabinets 3a, 3b, 3c, 3d, respectively, in turn, for introducing cold air supplied by the cooling apparatus 40 into the front spaces of cabinets from the top. It is preferable that each downward-extending portion 4110 is not longer than 30 cm in length without the effect on the guidance of cold air in the pipeline. Similarly, the third pipeline 412 is connected below the cooling apparatus 40, and is provided, along the path in the single flowing direction, with a plurality of upward-extending portions 4120 communicated to the bottom of the front spaces of cabinets 3a, 3b, 3c, 3d, respectively, in turn, for introducing cold air supplied by the cooling apparatus 40 into the front spaces from the bottom, each upward-extending portion 4120 having a length not longer than 30 cm being preferred. As for the second pipeline (the hot communicating pipeline 42), it is connected to the top of the cooling apparatus and the rear spaces of cabinets for recycling hot air discharged from the cabinets to the cooling apparatus 40.

In this embodiment, each cabinet 3a, 3b, 3c, 3d is provided with a plurality of temperature sensing units 23 (provided in the rear space) signalingly connected to a built-in adjuster 34a, 34b, 34c, 34d, while each adjuster 34a, 34b, 34c, 34d is, additionally, signalingly connected to a front air distribution unit 122 and a rear air distribution unit 222 (not shown, as referring to FIGS. 7 and 8 cooperatively) of the cabinet to which the adjuster belongs. The number of the temperature sensing units 23 may be determined depending upon the size of the cabinet 3a, 3b, 3c, 3d, and may be two, three, four or more distributed in different heights inside the cabinet, for sensing the temperature at the position where the temperature sensing unit is located as the basis of demand for cooling. It is implied that the position is required to be cooled when elevated temperature is sensed, such that cold air supplied to this position should be increased. On the contrary, it is implied that the position is supplied with more cold air than what is required when the lowered temperature is sensed, such that cold air supplied to this position may be reduced. The adjuster 34a, 34b, 34c, 34d, moreover, is allowed to receive the demand for cooling from each temperature sensing unit 23 in the cabinet to which the adjuster belongs, and the position where the cooling is required may be then determined. Further, the speed of cold air flowing from each of the first and third pipelines 411, 412 is regulated by controlling the front air distribution unit 122, while the speed of hot air flowing toward the second pipeline is regulated by controlling the rear air distribution unit 222. The front air distribution unit 122 is provided at the connection between the front space and each of the first and third pipelines 411, 412. Similarly, a first air distribution unit 1221 at the top and a third air distribution unit 1222 at the bottom are defined, in accompany with the definition of pipelines, for regulating the flow rate of cold air introduced from top and bottom, respectively. Moreover, the rear air distribution unit 222 is defined as a second air distribution unit, provided at the connection between the rear space and the second pipeline for regulating the speed of hot air within the cabinet discharged toward the second pipeline.

In one embodiment illustrated in FIGS. 13 to 15, it is supposed that the cooling apparatus 40 are connected to four cabinets 3a, 3b, 3c, 3d, with the assumption of the maximum total demand of the four cabinets 3a, 3b, 3c, 3d being 50 k (roughly indicating the consumed output power of air conditioning, with the assumptions of maximum consumption in each of the cabinets 3a, 3b being 15 k, the maximum consumption in the cabinet 3c being 12 k, and the maximum consumption in the cabinet 3d being 8 k), in such a way that at least 50 k output power of air conditioning should be provided by the cooling apparatus 40 to meet the possible demand of the cabinets 3a, 3b, 3c, 3d connected thereto. In addition, a controller 43 built in the cooling apparatus 40 is signalingly connected to each adjuster 34a, 34b, 34c, 34d of the cabinet 3a, 3b, 3c, 3d, so as to acquire the cooling demand of each cabinet 3a, 3b, 3c, 3d simultaneously, and to adjust the output of air conditioning of the cooling apparatus 40 (the amount of cold air supplied to the first and third pipelines 411, 412, respectively) depending upon the intensity of demand and the position where the demand comes from. Generally, the operation state, and also heat generation (cooling demand) of the electronic equipment in each cabinet 3a, 3b, 3c, 3d is distinct. Assuming a state of low demand (such as low speed or resting state) of each electronic equipment firstly in FIG. 13, the demand of the cabinets 3a, 3b is 4 k (2 k in at the top and 2 k at the bottom, respectively), the demand of the cabinet 3c is 3 k (1.5 k at the top and 1.5 k at the bottom, respectively), as well as the demand of the cabinet 3d is 2 k (1 k at the top and 1 k at the bottom, respectively). Thereby, information of the demand of each cabinet 3a, 3b, 3c, 3d is received by the controller 43 from each adjuster 34a, 34b, 34c, 34d to be counted, as well as the total output of air conditioning of the cooling apparatus 40 is then adjusted to be 13 k, and distributed to the first and third pipelines 411, 412 (6.5 k in each pipeline in this figure) depending upon the position where the demand comes from. Further, each adjuster 34a, 34b, 34c, 34d of the cabinet 3a, 3b, 3c, 3d is capable of regulating and controlling the flow rate of each of the first and third air distribution units 1221, 1222 depending upon its own demand, in such a way that an appropriate amount of cod air from the first and third pipelines 411, 412 may be intercepted without acquiring too much cold air. Thereby, the first and third pipelines 411, 412 with one single flowing direction is capable of providing cold air to each cabinet 3a, 3b, 3c, 3d in the path certainly, so as to meet the cooling demand of each cabinet 3a, 3b, 3c, 3d.

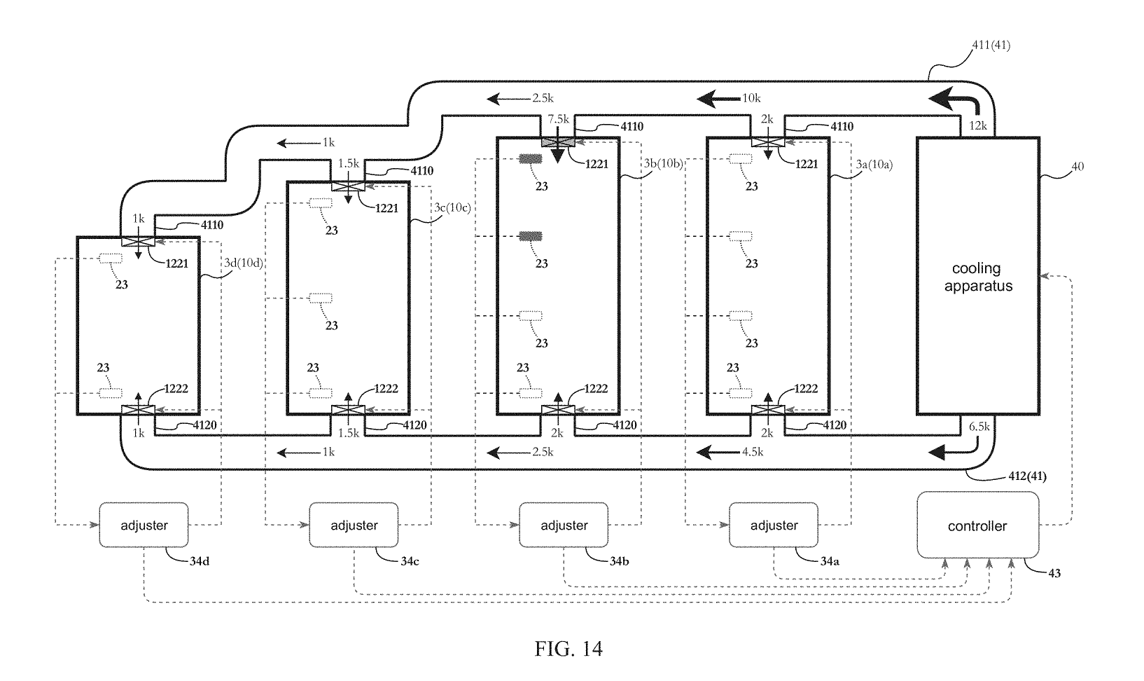

The cooling demand is varied as illustrated in FIG. 14, in which elevated temperature is sensed by the temperature sensing unit 23 at the top of the cabinet 3b (indicating raised performance of electronic equipment at the top within the cabinet 3b). It is implied that the cooling demand at the top of the cabinet 3b is increased (the specific demand being determined depending upon the variation of temperature, with the assumption that the demand at the top is varied to 7.5 k in this example). This demand is returned to the adjuster 34b and the controller 43 in real time as the basis for the controller 43 to adjust the increased output of air conditioning of the cooling apparatus 40. Thus, the amount of cold air supplied to the first pipeline 411 is increased to 12 k from 6.5 k due to the increased demand at the top, while the amount of cold air supplied to the third pipeline 412 is remained at original 6.5 k due to the unchanged demand at the bottom. At this time, the adjuster 34a of the cabinet 3a is still allowed for regulating and controlling the flow rate of the first and third air distribution units 1221, 1222 depending upon its own demand, in such a way that the cold air of 2 k is intercepted in each of the first and third pipelines 411, 412, respectively. Subsequently, the cold air of 10 k remained in the first pipeline 411 and the cold air of 4.5 k remained in the third pipeline 412 are allowed to flow toward the cabinet 3b continuously. The adjuster 34b of the cabinet 3b is allowed for controlling the first air distribution unit 1221 to increase the flow rate so as to acquire the cold air of 7.5 k from the first pipeline 411, while controlling the second air distribution unit 1222 to keep the flow rate unchanged so as to consistently acquire the cold air of 2 k from the third pipeline 412. In each of the first pipeline 411 and the third pipeline 412, the cold air of 2.5 k is respectively remained to flow toward the cabinet 3c continuously. The adjuster 34c of the cabinet 3c is allowed for regulating and controlling the flow rate of the first and third air distribution units 1221, 1222 depending upon its own demand, so as to acquire the cold air of 1.5 k from each of the first and third pipelines 411, 412, respectively, as well as the cold air of 1 k remained in each of the first pipeline 411 and the third pipeline 412 is allowed to flow toward the cabinet 3d continuously. The adjuster 34d of the cabinet 3d is similarly allowed for regulating and controlling the flow rate of the first and third air distribution units 1221, 1222 depending upon its own demand, so as to acquire the finally remaining cold air of 1 k in each of the first and third pipelines 411, 412 (The temperature of the interior of the cabinet 3d should be elevated in case of insufficient cold air being remained, such that the demand for cooling more is then issued from the cabinet 3d at this time, so as to obtain sufficient cold air.)

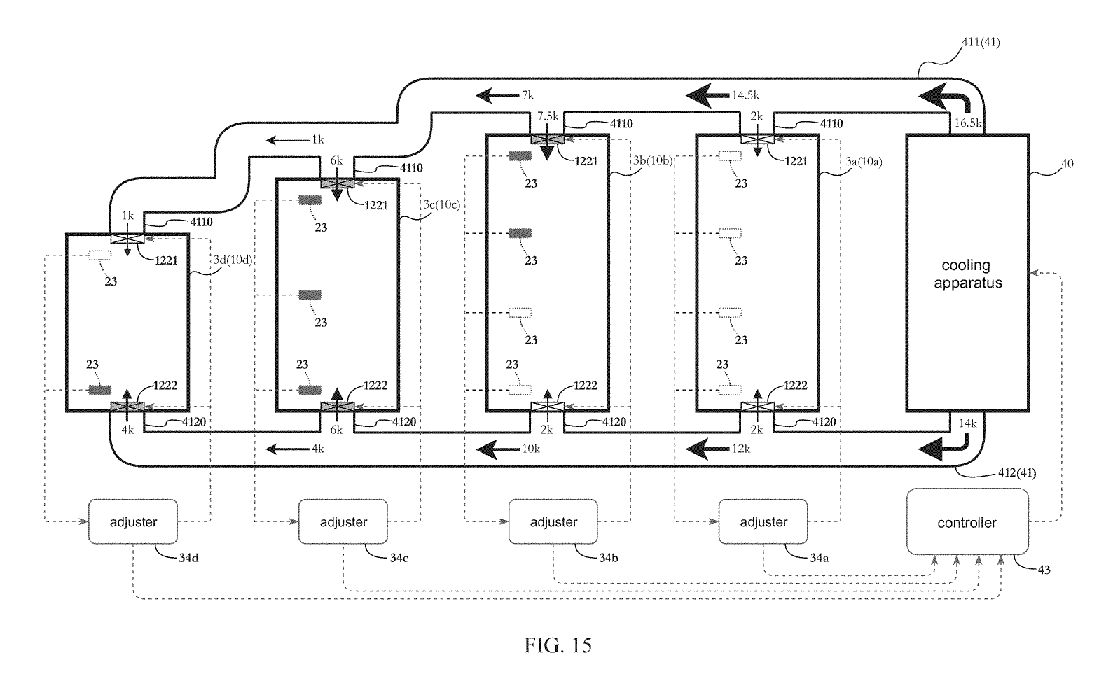

Similarly, the cooling demands of most of the cabinets are varied, further as illustrated in FIG. 15, in which elevated temperature is sensed by the temperature sensing units 23 at the top of the cabinet 3b, the top and the bottom of the cabinet 3c, the bottom of the cabinet 3d, indicating heat of the electronic equipment at these positions is increased and the cooling demand thereof is then increased (assuming that the demand at the top of the cabinet 3b is varied to 7.5 k, the demand an each of the top and bottom of the cabinet 3c is varied to 6 k, and the demand at the bottom of the cabinet 3d is varied to 4 k). These changes of demands are returned to the adjuster 34b, 34c, 34d and the controller 43 in real time as the basis for the controller 43 to adjust the increased output of air conditioning of the cooling apparatus 40 depending upon the magnitude of demand and the position where the demand comes from. Thus, the amount of cold air supplied to the first pipeline 411 is increased to 16.5 k, while the amount of cold air supplied to the third pipeline 412 is increased to 14 k. At this time, the adjuster 34a of the cabinet 3a is still allowed for regulating and controlling the flow rate of the first and third air distribution units 1221, 1222 depending upon its own demand, in such a way that the cold air of 2 k is intercepted in each of the first and third pipelines 411, 412, respectively. Subsequently, the cold air of 14.5 k remained in the first pipeline 411 and the cold air of 12 k remained in the third pipeline 412 are allowed to flow toward the cabinet 3b continuously. The adjuster 34b of the cabinet 3b is allowed for controlling the first air distribution unit 1221 to acquire the cold air of 7.5 k from the first pipeline 411, while controlling the third air distribution unit 1222 to acquire the cold air of 2 k from the third pipeline 412, depending upon the demand, as well as the cold air of 7 k remained in the first pipeline 411 and the cold air of 10 k remained in the third pipeline 412 are allowed to flow toward the cabinet 3c continuously. The adjuster 34c of the cabinet 3c is allowed for controlling each of the first and third air distribution units 1221, 1222, to acquire the cold air of 6 k from each of the first and third pipelines 411, 412, respectively, depending upon the demand, as well as the cold air of 1 k remained in the first pipeline 411 and the cold air of 4 k remained in the third pipeline 412 are allowed to flow toward the cabinet 3d continuously. The adjuster 34d of the cabinet 3d is similarly allowed for controlling the first air distribution unit 1221 to acquire the remaining cold air of 1 k from the first pipeline 411, while controlling the third air distribution unit 1222 to acquire the remaining cold of 4 k from the third pipeline 412 depending upon the demand.

To sum up, a smart cooling system applied to an electronic equipment room is constituted by the application of the air conditioning guiding system and air conditioning guiding module disclosed in the present invention, in which cold air may be supplied definitely in one single path on the basis of the demand of each cabinet, and cooling performance of providing cold air to a position where the demand for cold air comes from is achieved certainly by guiding cold air in a targeted way on the basis of different positions of heat source in different cabinets. Therefore, the efficacy of air conditioning and energy-saving effect are improved, the requirement for large space for planning air conditioning in a conventional electronic equipment room is also improved, and the cost is reduced. Thus, the present invention is novel and progressive, such that the inventor applies for a patent according to the law.

Descriptions illustrated above are only preferred embodiments of the present invention. Simple modifications, variations or equivalent replacement according to technical features and scope of the present invention are included in claims of the present invention.

What is claimed is:

1. A smart cooling system for an electronic equipment room, comprising a cooling apparatus and a plurality of cabinets, said cooling apparatus being used for cooling said plurality of cabinets, characterized by:
said cooling apparatus defining a controller to adjust output of air conditioning;
said plurality of cabinets, each having an accommodating space therein for locating electronic equipment, each cabinet further comprising a front extension frame forming a front space communicated to said accommodating space, and a rear extension frame forming a rear space communicated to said accommodating space;
a first pipeline connected to said cooling apparatus and communicated to said front spaces of said cabinets in turn in one single path, for supplying cold air to said front spaces from said cooling apparatus;
a second pipeline connected said cooling apparatus and communicated to said rear spaces of said cabinets, for recycling hot air to said cooling apparatus from said cabinets;
at least one temperature sensing unit provided in said rear space of each cabinet to acquire a cooling demand of each cabinet;
a first air distribution unit provided in said front space of each cabinet to regulate the speed of cold air flowing inwards from said first pipeline according to said cooling demand of each cabinet; and
a second air distribution unit provided in said rear space of each cabinet to regulate the speed of hot air flowing toward said second pipeline according to said cooling demand of each cabinet;
wherein said controller is allowed for regulating output of air conditioning of the cooling apparatus according to said cooling demands of said cabinets.

2. The smart cooling system as claimed in claim 1, wherein said first pipeline is communicated to an upper side of said front space of each cabinet.

3. The smart cooling system as claimed in claim 2, wherein said second pipeline is communicated to an upper side of said rear space of each cabinet.

4. The smart cooling system as claimed in claim 3, wherein said temperature sensing unit is provided in an upper position of said rear space of each cabinet.

5. The smart cooling system as claimed in claim 3, wherein said first pipeline is provided with a plurality of downward-extending portions connecting to an upper side of said front extension frame of each cabinet.

6. The smart cooling system as claimed in claim 5, wherein each downward-extending portion is not longer than 30 cm in length.

7. The smart cooling system as claimed in claim 5, wherein a third pipeline is connected to said cooling apparatus and communicated to lower sides of said front spaces of said cabinets in turn in one single path for supplying cold air to said front spaces from said cooling apparatus.

8. The smart cooling system as claimed in claim 7, wherein each third air distribution unit is provided in said front space of each cabinet to regulate the speed of cold air flowing inwards from the third pipeline according to said cooling demand of each cabinet.

9. The smart cooling system as claimed in claim 8, wherein said third pipeline is provided with a plurality of upward-extending portions connecting to a lower side of said front extension frame of each cabinet.

10. The smart cooling system as claimed in claim 9, wherein each downward-extending portion and upward-extending portion is not longer than 30 cm in length.

11. The smart cooling system as claimed in claim 8, wherein each rear extension frame of said cabinet is further provided with two temperature sensing units, defined as an upper temperature sensing unit and a lower temperature sensing unit, respectively, for acquiring cooling demands at the top and bottom of each cabinet.

12. The smart cooling system as claimed in claim 11, wherein said first air distribution unit is allowed to regulate the speed of cold air flowing inwards from the first pipeline according to said cooling demand at the top of each cabinet, while each third air distribution unit is allowed to regulate the speed of cold air flowing inwards from said third pipeline according to said cooling demand at the bottom of each cabinet.

13. The smart cooling system as claimed in claim 10, wherein each rear extension frame of said cabinet is further provided with two temperature sensing units, defined as an upper temperature sensing unit and a lower temperature sensing unit, respectively, for acquiring cooling demands at the top and bottom of each cabinet.

14. The smart cooling system as claimed in claim 13, wherein said first air distribution unit is allowed to regulate the speed of cold air flowing inwards from the first pipeline according to said cooling demand at the top of each cabinet, while each third air distribution unit is allowed to regulate the speed of cold air flowing inwards from said third pipeline according to said cooling demand at the bottom of each cabinet.

15. The smart cooling system as claimed in claim 8, wherein a plurality of temperature sensing units are respectively located at positions from upper to lower side of said rear space for acquiring cooling demands at upper to lower positions of each cabinet.

16. The smart cooling system as claimed in claim 15, wherein said first air distribution unit is allowed to regulate the speed of cold air flowing inwards from said first pipeline according to said cooling demand at the top of each cabinet, while each third air distribution unit is allowed to regulate the speed of cold air flowing inwards from said third pipeline according to the cooling demand at the bottom of each cabinet.

17. The smart cooling system as claimed in claim 10, wherein a plurality of temperature sensing units are respectively located at positions from upper to lower side of said rear space for acquiring cooling demands at upper to lower positions of each cabinet.

18. The smart cooling system as claimed in claim 17, wherein said first air distribution unit is allowed to regulate the speed of cold air flowing inwards from said first pipeline according to said cooling demand at the top of each cabinet, while each third air distribution unit is allowed to regulate the speed of cold air flowing inwards from said third pipeline according to the cooling demand at the bottom of each cabinet.

19. The smart cooling system as claimed in claims 17, wherein said front space is further used by said front extension frame to accommodate at least one power distribution device or at least one cabling management device.

20. The smart cooling system as claimed in claims 17, wherein said front extension frame is installed with a power distribution device in said front space, and said power distribution device is provided on one side thereof with a plurality of power supply units spaced from each other, each power supply unit being corresponded to a location reserved for accommodating an electronic equipment in said cabinet.
